(19) United States
(12) Patent Application Publication
(10) Pub. No.: US 2014/0036565 A1
(43) Pub. Date: Feb. 6, 2014

(54) MEMORY DEVICE AND METHOD OF MANUFACTURING MEMORY STRUCTURE

(71) Applicants: Shian Jyh LIN, Yonghe City (TW); Jen Jui Huang, Taoyuan County (TW)

(72) Inventors: Shian Jyh LIN, Yonghe City (TW); Jen Jui Huang, Taoyuan County (TW)

(73) Assignee: Nanya Technology Corporation, Tao-Yuan Hsien (TW)

(21) Appl. No.: 13/565,289

(22) Filed: Aug. 2, 2012

(51) Int. Cl. H01L 21/768; G11C 5/06

(52) U.S. Cl. 365/63; 438/637; 257/E21.585

(57) ABSTRACT

An exemplary memory device includes a substrate and two word lines extending on the substrate. The substrate includes an active area. The two word lines are formed on the active area. Each word line includes a recessed portion corresponding to the active area. The recessed portion is defined by a planar top surface.

### BACKGROUND OF THE INVENTION

1. Technical Field

The present invention relates to a memory device and a method of manufacturing a memory device structure.

2. Background

Semiconductor devices are being made in smaller and smaller sizes to be more compact for mobile computing applications and to consume less energy to extend battery life between charges. The technology used to reduce the size of semiconductor devices can also facilitate increases in circuit density so as to allow the semiconductor devices to have more computing power. Technological advances to date have been consistently limited by the resolution of photolithographic equipment available at a given time.

The minimum sizes of features and spaces are directly related to the resolution capability of photolithographic equipment. In semiconductor devices, repeating patterns, typical of memory arrays, are measured by a pitch that is defined as the distance between identical points in two adjacent features. Generally, the pitch can be viewed as the sum of the width of a feature and the width of a space or material separating two adjacent features. Limited by the resolution of available photolithographic equipment, features below a minimum pitch cannot be reliably obtained.

One-half of the minimum pitch is commonly defined as a feature size F, which is often referred to as the resolution of photolithographic equipment. The minimum pitch, 2 F, places a theoretical limit on the size reduction of semiconductor devices.

Pitch doubling is one method that allows semiconductor device manufacturers to produce repeating patterns having a pitch less than the minimum pitch 2 F provided by current photolithographic technologies. Pitch doubling techniques are illustrated and described in U.S. Pat. No. 5,328,810 and U.S. Pat. No. 7,115,525. In a process of pitch doubling, a primary photoresist mask is created using conventional photolithography. The primary photoresist mask has parallel photoresist strips each having a feature size F. Adjacent strips are separated by a space, which has a size equal to F. The photoresist strips are then subjected to an oxygen plasma etch process to halve their widths to form reduced strips. The material with a high degree of selectivity is then deposited, and thereafter anisotropically etched to form side strips on the sidewalls of each reduced strip. The reduced strips are then removed with a selective etch, and the side strips 10 remain as shown in FIG. 1. The side strips 10 can be used as a half-pitch mask to pattern the underlying layer 11 to form a plurality of trenches 12a and 12b as shown in FIG. 2.

As can be seen in FIG. 2, the conventional pitch doubling process cannot easily form uniform spaces between the side strips 10, and as a result, the trenches 12a and 12b in the underlying layer 11 may have different depths and widths.

### SUMMARY

One embodiment discloses a memory device, which comprises a substrate and two word lines extending on the substrate. The substrate may comprise an active area. The two word lines are formed on the active area. Each word line may comprise a recessed portion corresponding to the active area. The recessed portion may be defined by a planar top surface.

In some embodiments, the planar top surfaces of the recessed portions of the two word lines may be equal.

In some embodiments, the recessed portion is defined by a side surface and a top surface connecting to the side surface, wherein a round corner is formed between the top surface and the side surface.

In some embodiments, the width difference between the two word lines is not greater than 1 nanometer.

Another embodiment discloses a method of manufacturing a memory device structure. The method comprises forming a first layer on a substrate and a second layer on the first layer, patterning the second layer to obtain a line-and-space pattern comprising a plurality of lines and a plurality of first spaces, forming a spacer layer on the line-and-space pattern, depositing fill material in the first spaces, forming a plurality of second spaces by removing the spacer layer on side surfaces of the lines, forming a plurality of third spaces in the first layer via the plurality of second spaces, etching the substrate via the plurality of third spaces to expose portions of the active areas, and forming a plurality of word lines in the substrate, wherein each word line extends on the corresponding ones of the active areas.

In some embodiments, the method further comprises a step of etching a stop layer between the first layer and the second layer through the plurality of second spaces.

In some embodiments, the method comprises a step of etching the second layer via a silicon oxynitride mask.

In some embodiments, the first layer comprises carbon.

In some embodiments, the second layer comprises carbon.

In some embodiments, the first layer is transparent.

In some embodiments, the second layer is transparent.

In some embodiments, the fill material comprises amorphous silicon.

In some embodiments, the spacer layer comprises atomic layer deposition oxide.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention are illustrated with the following description and upon reference to the accompanying drawings in which:

FIG. 1 schematically illustrates a half-pitch mask formed by a conventional pitch doubling process;

FIG. 2 schematically illustrates trenches formed by a half-pitch mask formed by a conventional pitch doubling process;

FIG. 3 schematically illustrates word lines on active areas on a substrate, all included in a memory device according to one embodiment;

FIG. 4 schematically illustrates two active areas and one word line according to one embodiment; and

FIGS. 5 through 12 are cross-sectional views showing the steps of a method of manufacturing a memory device structure according to one embodiment.

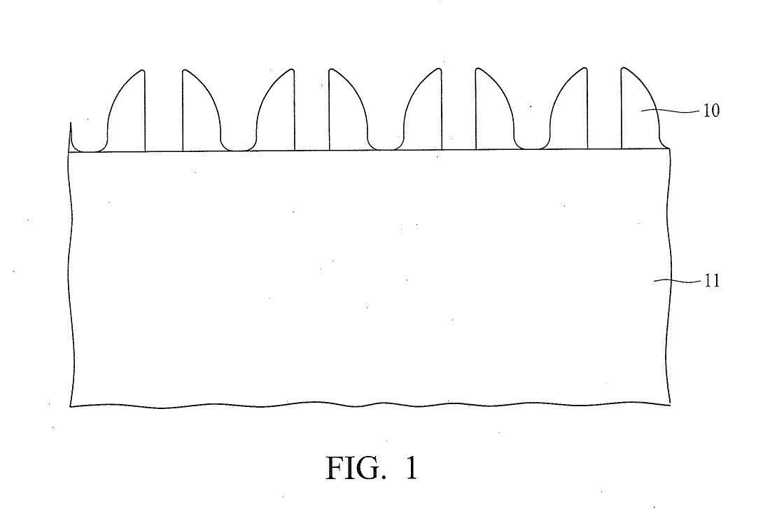

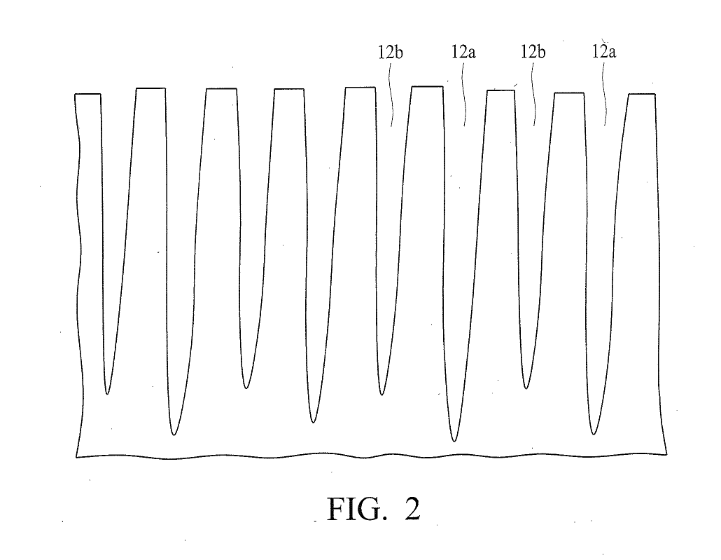

### DETAILED DESCRIPTION

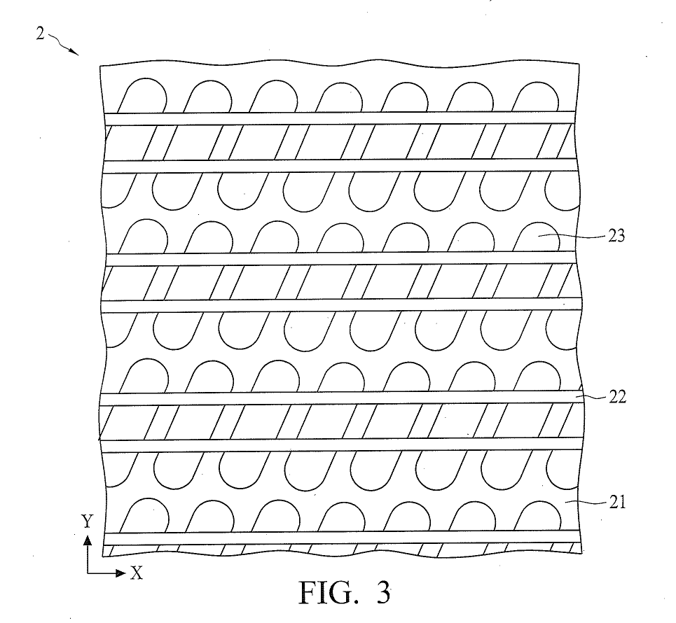

FIG. 3 schematically illustrates word lines 22 on active areas 23 on a substrate 21, all included in a memory device 2 according to one embodiment. As shown in FIG. 3, a memory device 2 may comprise a substrate 21 and a plurality of word lines 22 extending on the substrate 21. The substrate 21 may comprise a plurality of active areas 23. The plurality of active areas 23 can align along either one of the x and y axes. The active area 23 may, but is not limited to, be oblique relative to either the x or y axes. The active area 23 can have an elongated shape. The active areas 23 represent a doped region or well within the substrate 21; however, in other embodiments, the active areas 23 need not represent physical structures or materials within or upon the memory device 2. The active areas 23 define the portions of the memory device 2 that contain field effect transistors and are typically surrounded by field isolation elements, for example, shallow trench isolation. In some embodiments, each active area 23 may comprise two drains and one source. The active area pattern can be fabricated by a variety of methods, including a lithographic process and an etching process, well-known to those skilled in the art.

The plurality of word lines 22 may have a pitch less than the minimum pitch defined by the photolithographic technique. For example, the pitch of the word lines 22 may be equal to one-half the minimum pitch defined by the photolithographic technique. These word lines 22 may have a similar width and/or height. In some embodiments, two adjacent word lines 22 extending on the same row of active areas 23 may have a width difference that is not greater than 1 nanometer.

In some embodiments, the word lines 22 may comprise an n-type semiconductor such as silicon doped with phosphorus. In other embodiments, the word lines 22 may comprise metal including TiN, metal silicide, tungsten or the combination thereof, or other materials contain Hf, and others which are able to match with high-K gate dielectric.

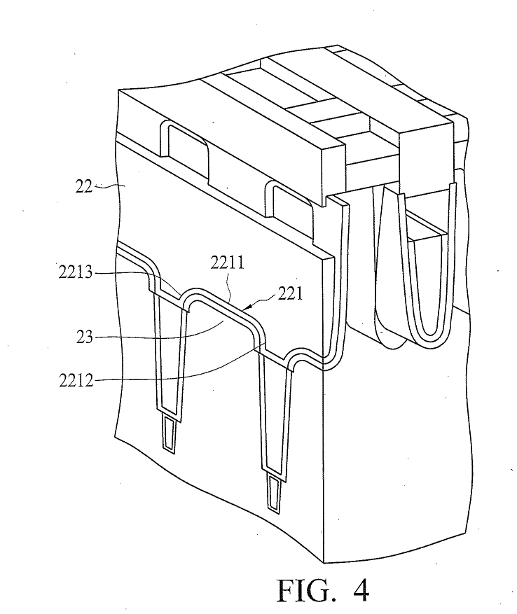

FIG. 4 schematically illustrates a word line 22 extending across an active area 23 according to one embodiment. As illustrated in FIG. 4, each word line 22 is formed across a plurality of active areas 23 and is electrically isolated from the active areas 23 by, for example, a gate oxide layer. The word line 22 comprises recessed portions 221 mated with the corresponding active areas 23. The recessed portion 221 may comprise a top surface 2211 and two side surfaces 2212 and 2213. The top surface 2211 may comprise a planar surface. In some embodiments, the top surface 2211 may connect to the side surface 2212, and a round corner is formed between the top surface 2211 and the side surface 2212. In some embodiments, the top surface 2211 may connect to the side surface 2213, and a round corner is formed between the top surface 2211 and the side surface 2213. In some embodiment, the top surfaces 2211 of two word lines 22 extending on the same row of active areas 23 are substantially equal.

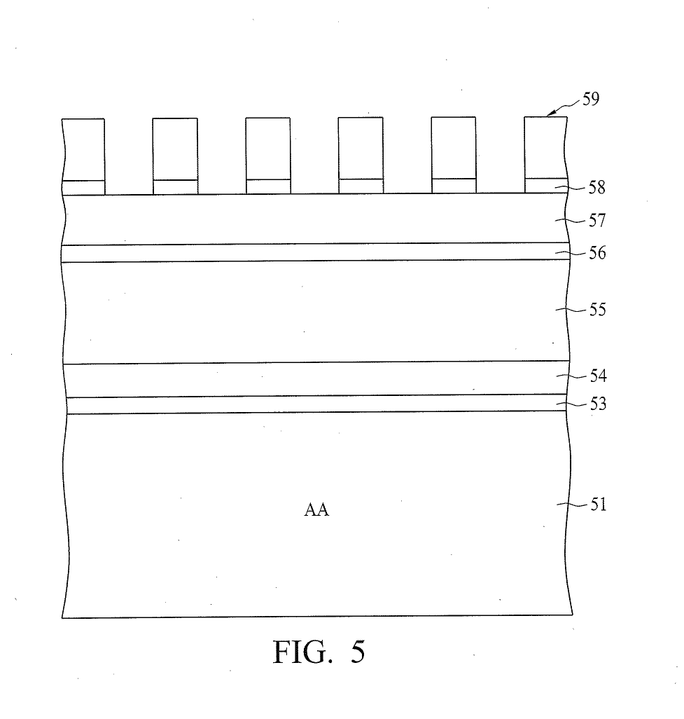

FIGS. 5 through 12 are cross-sectional views showing the steps of a method of manufacturing a memory device structure according to one embodiment. Referring to FIG. 5, a nitride layer 54, with a thickness of approximately, but not limited to, 70 nanometers, is formed on a substrate 51, which may comprise a plurality of active areas (AAs). In some embodiments, a buffer layer 53 such as an oxide layer can be formed between the substrate 51 and the nitride layer 54.

Next, a first layer 55 with a thickness of approximately, but not limited to, 200 nanometers, is formed on the nitride layer 54. In some embodiments, the first layer 55 may comprise carbon. In some embodiments, the first layer 55 may be a carbon film. In some embodiments, the first layer 55 may comprise carbon-contained material including CₓH_{y}. In some embodiments, the first layer 55 may be transparent.

Next, a stop layer 56 with a thickness of approximately, but not limited to, 35 nanometers, is formed on the first layer 55. In some embodiments, the stop layer 56 may comprise nitride.

Next, a second layer 57 with a thickness of approximately, but not limited to, 100 nanometers, is formed on the stop layer 56. In some embodiments, the second layer 57 may be a carbon film. In some embodiments, the second layer 57 may comprise carbon. In some embodiments, the second layer 57 may comprise carbon-contained material including CₓH_{y}. In some embodiments, the second layer 57 may be transparent.

In some embodiments, the first layer 55 can be thicker than the second layer 57. In some embodiments, the first layer 55 is twice as thick as the second layer 57.

Furthermore, a mask layer 58 is formed on the second layer 57. In some embodiments, the mask layer 58 may be a silicon oxynitride mask.

Referring to FIG. 5 again, a photoresist layer 59 is deposited on the mask layer 58, patterned to form a line-and-space pattern. The line-and-space pattern can have a minimum pitch that is achievable with current photolithographic equipment. The lines can have substantially the same line width, and can be equally spaced from each other. Next, the mask layer 58 is etched by a dry etch process.

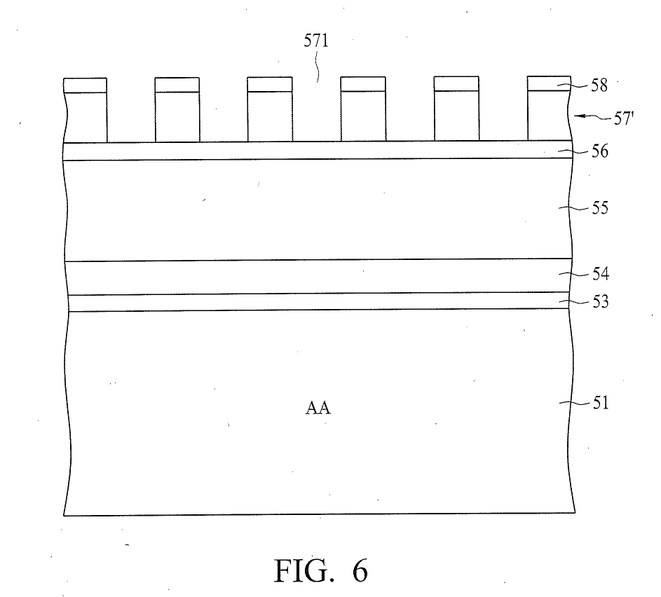

Referring to FIG. 6, the photoresist layer 59 (FIG. 5) is stripped. An etch process, for example a dry etch process, is performed to pattern the second layer 57, and a line-and-space pattern 57′ including a plurality of spaces 571 is obtained.

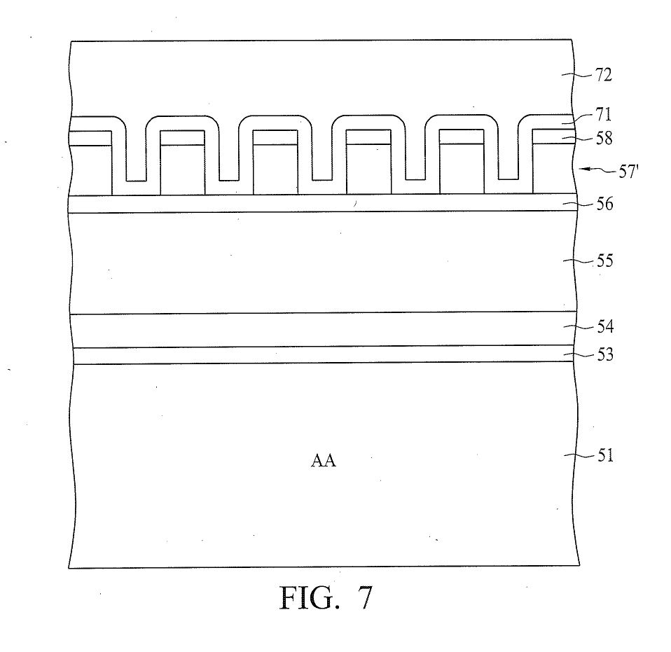

Referring to FIG. 7, a spacer layer 71 is formed or deposited on the line-and-space pattern 57′. In some embodiments, the spacer layer 71 comprises oxide. Preferably, in some embodiments, the spacer layer 71 comprises atomic layer deposition oxide. In some embodiments, the spacer layer 71 is formed by atomic layer deposition (ALD).

The thicknesses of the spacer layer 71 on the side surfaces of the lines of the line-and-space pattern 57′ determine the widths of the word lines 22 (FIG. 3) formed later. Because such thicknesses can be formed uniformly, the widths of the word lines 22 can be substantially equivalent.

Referring to FIG. 7 again, a material 72 is next deposited on the spacer layer 71. In some embodiments, the material 72 comprises amorphous silicon. In some embodiments, the material 72 is deposited by a low temperature amorphous silicon deposition. In some embodiments, the material 72 is deposited by a low temperature amorphous silicon deposition at a temperature of less than, for example, 500 degrees Celsius.

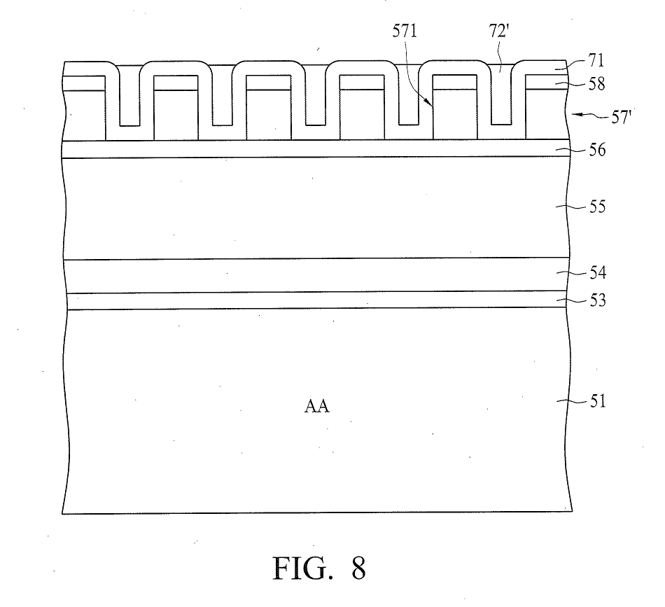

Referring to FIG. 8, the portion of the material 72 above the spacer layer 71 on the tops of the line-and-space pattern 57′ is removed, leaving behind a fill material 72′ that is located in the spaces of the line-and-space pattern 57′. In some embodiments, the portion of the material 72 can be removed using a chemical mechanical polishing (CMP) or dry etch process, which may be stopped on the spacer layer 71.

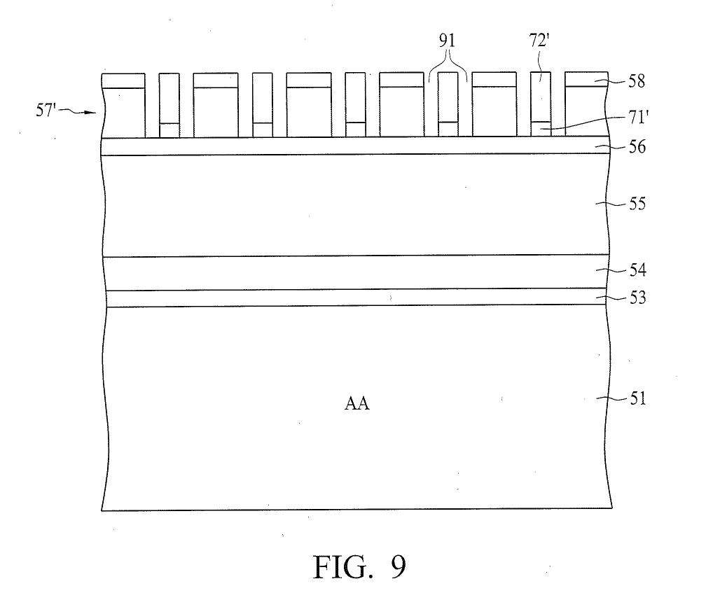

Referring to FIG. 9, an etch process is next performed to remove most of the spacer layer 71. The spacer layer 71 on the side surfaces of the lines of the line-and-space pattern 57′ are removed, leaving behind a plurality of spaces 91, which are used to define the widths of the word lines 22. Two adjacent spaces 91 are separated by either the line structure that comprises a portion of the mask layer 58 and a line of the line-and-space pattern 57′ or the line structure that comprises fill material 72′ and a spacer layer remnant 71′.

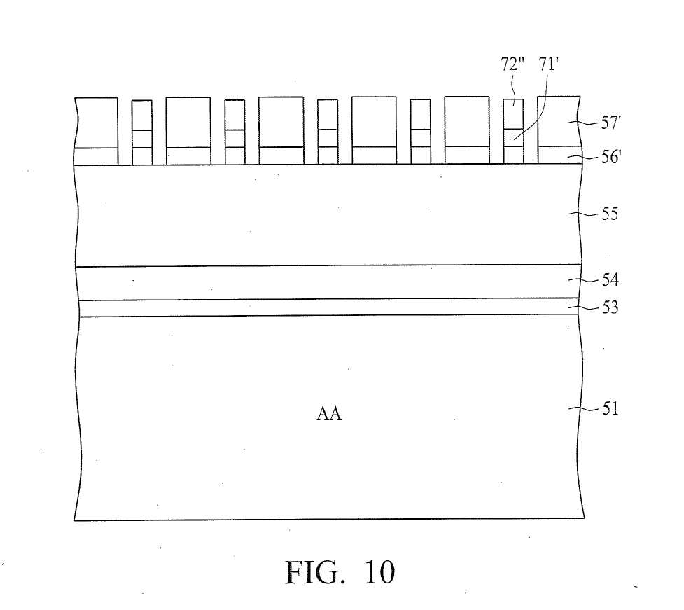

As shown in FIG. 10, an etch process, for example a dry etch process, is then employed to remove the stop layer 56 exposed in the spaces 91, resulting in a new stop layer 56′ with a plurality of spaces exposing portions of the underlying first layer 55.

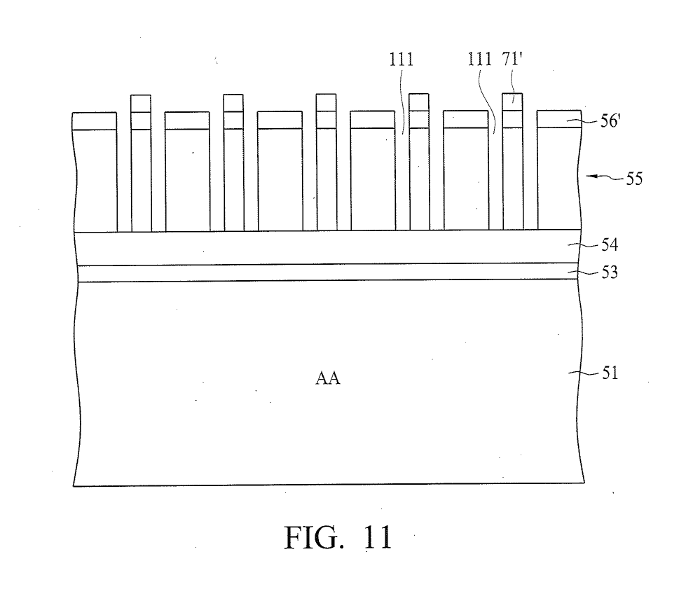

Referring to FIG. 11, a plurality of spaces 111 is formed in the first layer 55 through the spaces in the new stop layer 56′ and the spaces 91. The plurality of spaces 111 can be formed using an etch process such as a dry etch process.

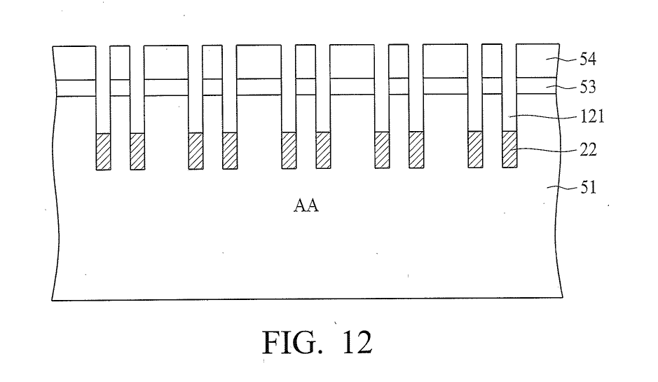

As shown in FIG. 12, the nitride layer 54 exposed in the spaces 111 is removed to expose the underlying layer 53 by, for example, a dry etch process. Next, a recess etch process is performed to etch the substrate 51 to obtain a plurality of spaces 121 to expose portions of the active areas (AAs). Thereafter, the first layer 55 is removed and plurality of word lines 22 are respectively formed in the spaces 121 in the substrate 51. Each word line 22 extends on corresponding active areas. The word lines 22 can be formed by any of plural methods well known to those having skill in the art.

Because the spaces 91 (shown in FIG. 9) in the line-and-space pattern 57′ have a substantially equal width, the spaces 111 (shown in FIG. 11) can be formed with a substantially equal depth. In addition, because the spaces 111 are formed with a substantially equal width, the word lines can have a substantially equal width. In some embodiments, a width difference of two word lines 22 on the active area is not greater than 1 nanometer. In comparison, using conventional methods, the width difference of two word lines on the active area is usually greater than 2 nanometers. Because two word lines 22 on the same active area are of similar or substantially equal width and/or height, the word line 22 may be formed with a recessed portion corresponding to the active area, which may comprise a top surface comprising a planar surface. In some embodiments, the planar surfaces of the word line 22 on the same active area can be substantially equivalent. Two uniform word lines 22 on the same active area can result in substantially similar electrical performance.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A memory device, comprising:
a substrate comprising an active area; and
two word lines formed on the active area, each word line comprising a recessed portion corresponding to the active area, the recessed portion defined by a planar top surface.

2. The memory device of claim 1, wherein the planar top surfaces of the recessed portions of the two word lines are equal.

3. The memory device of claim 1, wherein the recessed portion comprises a side surface connecting to the top surface, wherein a round corner is formed between the top surface and the side surface.

4. The memory device of claim 1, wherein a width difference between the two word lines is not greater than 1 nanometer.

5. A method of manufacturing a memory device structure, comprising the steps of:
forming a first layer on a substrate including a plurality of active areas and a second layer on the first layer;
patterning the second layer to obtain a line-and-space pattern comprising a plurality of lines and a plurality of first spaces;
forming a spacer layer on the line-and-space pattern;
depositing fill material in the first spaces;
forming a plurality of second spaces by removing the spacer layer on side surfaces of the lines;
forming a plurality of third spaces in the first layer via the plurality of second spaces; and
etching the substrate via the plurality of third spaces to expose portions of the active areas; and
forming a plurality of word lines in the substrate, wherein each word line extends on the corresponding ones of the active areas.

6. The method of claim 5, wherein each word line comprises a recessed portion comprising a planar top surface.

7. The method of claim 6, wherein the planar top surfaces of the recessed portions of two word lines on a same active area of the substrate are equal.

8. The method of claim 6, wherein the recessed portion comprises a side surface connecting to the top surface, wherein a round corner is formed between the top surface and the side surface.

9. The method of claim 5, wherein the step of patterning the second layer comprises a step of etching the second layer via a silicon oxynitride mask.

10. The method of claim 5, further comprising a step of etching a stop layer between the first layer and the second layer through the plurality of second spaces.

11. The method of claim 5, wherein the first layer comprises carbon.

12. The method of claim 5, wherein the second layer comprises carbon.

13. The method of claim 5, wherein the first layer is transparent.

14. The method of claim 5, wherein the second layer is transparent.

15. The method of claim 5, wherein the fill material comprises amorphous silicon.

16. The method of claim 5, wherein the spacer layer comprises atomic layer deposition oxide.

17. The method of claim 5, wherein a width difference of two word lines on a same active area is not greater than 1 nanometer.
